(19) United States
(12) Patent Application Publication
(10) Pub. No.: US 2025/0262634 A1
(43) Pub. Date: Aug. 21, 2025

(54) DEPOSITION SYSTEM

(71) Applicant: YAS CO. LTD., Paju-si (KR)

(72) Inventors: Myung Woon CHOI, Paju-si (KR); Hyun Uk KANG, Paju-si (KR); Su Hwan KIM, Paju-si (KR)

(73) Assignee: YAS CO. LTD., Paju-si (KR)

(21) Appl. No.: 19/203,939

(22) Filed: May 9, 2025

Related U.S. Application Data
(63) Continuation of application No. PCT/KR2023/015485, filed on Oct. 10, 2023.

(30) Foreign Application Priority Data
Nov. 11, 2022 (KR) 10-2022-0150614

(51) Int. Cl. B05B 13/02

(52) U.S. Cl. CPC B05B 13/0278; B05B 13/0228

(57) ABSTRACT

The present invention relates to a deposition system. According to an embodiment of the present invention, a deposition system including a plurality of evaporation sources includes a substrate and a plurality of point evaporation sources that spray a deposition material onto the substrate, and at least two of the plurality of point evaporation sources have different spraying directions.

### CROSS-REFERENCE TO RELATED PATENT APPLICATION

This application is a Continuation of International Application No. PCT/KR2023/015485, filed on Oct. 10, 2023, which claims the benefit of Korean Patent Application No. 10-2022-0150614, filed on Nov. 11, 2022, in the Korean Intellectual Property Office, the disclosure of which is incorporated herein in its entirety by reference.

### TECHNICAL FIELD

The present invention relates to a deposition system, and more particularly, to a deposition system including a plurality of point evaporation sources having different directions in which a deposition material is sprayed, to form a thin film on a substrate.

### BACKGROUND ART

As a scheme for depositing a thin film on a substrate, particularly a substrate for an organic light-emitting diode (OLED), a scheme for spraying a deposition material toward a front surface of a substrate using an evaporation source is generally used. A representative deposition scheme is a thermal deposition method, and in particular, a deposition method using a linear evaporation source and a deposition method using a point evaporation source are mainly used.

Among these, in the deposition using the point evaporation source, an evaporation material is accommodated in a cylindrical crucible, the crucible is heated, and the evaporation material is sprayed toward a front surface of a substrate through a nozzle coupled to an upper portion of the crucible so that deposition on the substrate is performed.

However, a conventional deposition system has a problem such as an edge-drop phenomenon, in which a deposition material is deposited more thinly at an edge of a substrate when an area of the substrate increases, resulting in a smaller thin film thickness toward the edge of the substrate.

Further, the conventional deposition system has a problem such as a center-drop phenomenon, in which a deposition material is deposited more thinly at a center of a substrate when a point evaporation source is located at the outer side from the center of the substrate, resulting in a smaller thin film thickness toward the center of the substrate.

Specifically, a conventional deposition system 100 is as shown in a structural diagram in FIG. 1. Referring to FIG. 1, a substrate 110 rotates around a center 113 of the substrate, a first point evaporation source 120a, a second point evaporation source 120b, and a third point evaporation source 120c are disposed below the substrate 110, and the respective point evaporation sources 120 spray an evaporation material in a direction perpendicular to the substrate 110.

A thickness of a thin film deposited on the substrate by the conventional deposition system 100 as in FIG. 1 is as shown in graphs in FIG. 2. A first thin film thickness 210 according to a distance of the substrate on which deposition is performed by the first point evaporation source 120a, a second thin film thickness 220 according to a distance of the substrate on which deposition is performed by the second point evaporation source 120b, and a third thin film thickness 230 according to a distance of the substrate on which deposition is performed by the third point evaporation source 120c are all the same. Therefore, an edge-drop phenomenon and a center-drop phenomenon of each of the first thin film thickness 210, the second thin film thickness 220, and the third thin film thickness 230 cause the non-uniformity of a total thin film thickness 260 according to a distance of the substrate.

Therefore, in the deposition system, the need to solve the non-uniformity of the thin film thickness due to the edge-drop phenomenon and the center-drop phenomenon is increasing.

Meanwhile, the background art described above is technical information that the inventor has possessed for the purpose of deriving the present invention or acquired while deriving the present invention, and therefore cannot necessarily be said to be known technology disclosed to the general public prior to the application of the present invention. (Prior art document) Korean Patent No. 10-1176998 (Aug. 20, 2012)

### DISCLOSURE

### Technical Problem

An object of the present invention is directed to providing a deposition system capable of performing uniform deposition on a substrate having a large area.

Another object of the present invention is directed to providing a deposition system that improves the uniformity of a thickness of a thin film deposited on a substrate by adjusting a spraying direction, spraying angle, or spraying amount of each of a plurality of point evaporation sources.

Still another object of the present invention is directed to providing a deposition system capable of preventing an edge-drop phenomenon or a center-drop phenomenon even when a plurality of point evaporation sources are disposed at the same horizontal distance from a rotation axis of a substrate.

Still another object of the present invention is directed to providing a deposition system capable of performing uniform deposition on a substrate even when a shape, area, rotation speed of the substrate, or a distance to the substrate varies, by adjusting a spraying amount of each of a plurality of point evaporation sources.

Still another object of the present invention is directed to providing a deposition system capable of adjusting a spraying angle and spraying force of each point evaporation source.

Still another object of the present invention is directed to providing a deposition system capable of improving the uniformity of a thickness of a thin film even when the deposition system is a revolver-type deposition system in which a disposition position of a point evaporation source is fixed.

The objects of the present invention are not limited to the objects mentioned above, and other objects that are not mentioned can be clearly understood by those skilled in the art from the description below.

### Technical Solution

In order to solve the problems described above, according to an aspect of the present invention, a deposition system includes a substrate, and a plurality of point evaporation sources configured to spray a deposition material onto the substrate, wherein at least two of the plurality of point evaporation sources have different spraying directions.

According to another aspect of the present invention, the at least two of the plurality of point evaporation sources may be disposed at substantially the same horizontal distance from a central axis of the substrate.

According to still another aspect of the present invention, the substrate may rotate around a central axis of the substrate, and a circular deposition region with a diagonal of the substrate as its diameter may be formed as the substrate rotates.

According to still another aspect of the present invention, the deposition region may include a circular central region, a center of the central region may be the same as the center of the substrate, the central region may have a diameter smaller than the deposition region, and at least one of the plurality of point evaporation sources may be a center spray point evaporation source configured to spray the deposition material toward the central region.

According to still another aspect of the present invention, the center spray point evaporation source may include a nozzle tilted a predetermined angle toward the central region to spray the deposition material toward the center region.

According to still another aspect of the present invention, a spraying amount of the center spray point evaporation source may be larger than that of at least one of the plurality of point evaporation sources.

According to still another aspect of the present invention, the deposition region may include an inner region in the shape of a ring, the inner region may have the same outer diameter as a diameter of the deposition region, and at least one of the plurality of point evaporation sources may be an inner-side spray point evaporation source configured to spray the deposition material toward the inner region.

According to still another aspect of the present invention, the inner-side spray point evaporation source may include a nozzle configured to spray the deposition material vertically toward the inner region.

According to still another aspect of the present invention, a spraying amount of the inner-side spray point evaporation source may be smaller than that of at least one of the plurality of point evaporation sources.

According to still another aspect of the present invention, at least one of the plurality of point evaporation sources may be an outer-side spray point evaporation source configured to spray the deposition material toward an outer region that is a region external to the deposition region.

According to still another aspect of the present invention, the outer-side spray point evaporation source may include a nozzle tilted a predetermined angle toward the outer region to spray the deposition material toward the outer region.

According to still another aspect of the present invention, a spraying amount of the outer-side spray point evaporation source may be larger than that of at least one of the plurality of point evaporation sources.

According to still another aspect of the present invention, the nozzles of the at least two of the plurality of point evaporation sources may have different diameters.

According to still another aspect of the present invention, the deposition system may further include a revolver including a first point evaporation source among the plurality of point evaporation sources and a first preliminary point evaporation source corresponding to the first point evaporation source, wherein the revolver rotates to move the first preliminary point evaporation source to a position of the first point evaporation source.

According to still another aspect of the present invention, the at least two of the plurality of point evaporation sources may spray different deposition materials.

### Advantageous Effects

According to any one of the solutions of the present invention, the deposition system can perform uniform deposition on a substrate having a large area.

According to any one of the solutions of the present invention the deposition system can improve the uniformity of a thickness of a thin film deposited on a substrate by adjusting a spraying direction, spraying angle, or spraying amount of each of a plurality of point evaporation sources.

According to any one of the solutions of the present invention the deposition system can prevent an edge-drop phenomenon or a center-drop phenomenon even when a plurality of point evaporation sources are disposed at the same horizontal distance from a rotation axis of a substrate.

According to any one of the solutions of the present invention, the deposition system can perform uniform deposition on a substrate even when a shape, area, rotation speed of the substrate, or a distance to the substrate varies, by adjusting a spraying amount of each of a plurality of point evaporation sources.

According to any one of the solutions of the present invention the deposition system can improve the uniformity of a thickness of a thin film deposited on a substrate by adjusting a spraying angle and spraying force of each point evaporation source.

According to one of the solutions of the present invention, the deposition system can prevent an edge-drop phenomenon or a center-drop phenomenon even when the deposition system is a revolver-type deposition system in which a disposition position of a point evaporation source is fixed.

The effects that can be obtained from the present invention are not limited to the effects mentioned above, and other effects that are not mentioned can be clearly understood by those skilled in the art to which the present invention belongs from the description below.

### DESCRIPTION OF DRAWINGS

FIG. 1 is a diagram illustrating a conventional deposition system.

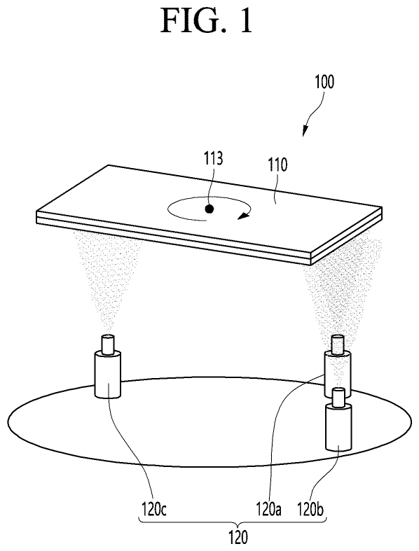

FIG. 2 is a graph showing a thin film thickness of a substrate on which deposition is performed by the conventional deposition system.

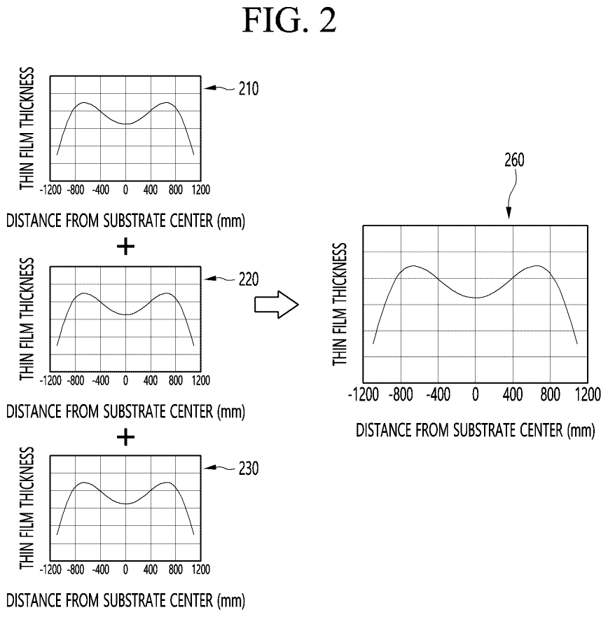

FIG. 3 is a diagram illustrating a deposition system according to an embodiment of the present invention.

FIG. 4 is a graph showing a thin film thickness of a substrate on which deposition is performed by the deposition system according to the embodiment of the present invention.

FIG. 5 is a graph showing a thin film thickness of a substrate on which deposition is performed by a deposition system according to another embodiment of the present invention.

FIG. 6 is a graph showing a thin film thickness of a substrate on which deposition is performed by a deposition system according to still another embodiment of the present invention.

FIG. 7 is a graph showing a thin film thickness of a substrate on which deposition is performed by a deposition system according to still another embodiment of the present invention.

FIG. 8 is a graph showing a thin film thickness of a substrate on which deposition is performed by a point evaporation source whose nozzle is replaced with a nozzle having a different diameter according to still another embodiment of the present invention.

FIG. 9 is a block diagram illustrating a deposition system according to still another embodiment of the present invention.

FIG. 10 is a graph showing a thin film thickness of a substrate on which deposition is performed by a deposition system in which each nozzle has an optimized diameter and spraying amount according to still another embodiment of the present invention.

FIG. 11 is a diagram illustrating a revolver-type deposition system viewed from a normal direction of a substrate according to still another embodiment of the present invention.

FIG. 12 is a diagram illustrating a deposition system according to still another embodiment of the present invention.

### MODES OF THE INVENTION

Specific details including the problem to be solved, the means for solving the problem, and the effects of the invention as described above are included in embodiments and drawings to be described below. The advantages and features of the present invention, and a method for achieving these will become apparent from the embodiments to be described below in detail with the accompanying drawings. However, the present invention is not limited to the embodiments disclosed below, but may be implemented in various different forms. The embodiments are provided only to completely disclose the present invention and to fully inform those skilled in the art to which the present invention belongs of the scope of the invention. In other words, the present invention is defined only by the claims.

Since shapes, sizes, proportions, angles, numbers, and the like disclosed in the drawings for describing the embodiments of the present invention are illustrative, the present invention is not limited to matters illustrated. Further, when it is judged that detailed description of related known technology may unnecessarily obscure the gist of the present invention in describing the present invention, detailed description thereof will be omitted. When “includes,” “have,” “consist of,” or the like mentioned herein is used, other parts may be added unless “only” is used. When a component is expressed in a singular form, a plural form is included unless specified otherwise.

When a component is construed, a range of errors is construed as being included even when there is no separate explicit description. Further, “substantially the same” mentioned herein is interpreted as not only being completely the same in terms of values, but also an error range generally generated by those skilled in the art being applied.

Although the first, second, and the like are used to describe various components, the components are not limited by such terms. These terms are only used to distinguish one component from another. Therefore, a first component mentioned below may be a second component within the technical spirit of the present invention.

Unless specified otherwise, the same reference signs refer to the same components throughout the specification.

Features of the various embodiments of the present invention may be partially or entirely coupled or combined with each other, and as can be fully understood by those skilled in the art, a variety of technical linkage and driving are possible, and the embodiments may be implemented independently of each other or may be implemented together in association with each other.

Hereinafter, the terms used herein are defined.

Uniformity may be understood as a value representing the uniformity of a thin film deposited on a substrate. The more uniformly a deposition material is deposited on the substrate, the smaller the uniformity value becomes. Formula 1 below may be used as a method for calculating the uniformity. However, the method for calculating the uniformity is not limited thereto, and various uniformity calculation methods may be used.

$$[ Formula 1 ]$$

$$Uniformity [ \% ] = \frac{Max thin film thickness - Min thin film thickness}{2} \div Average thin film thickness$$

Hereinafter, the present invention will be described in detail with reference to the accompanying drawings.

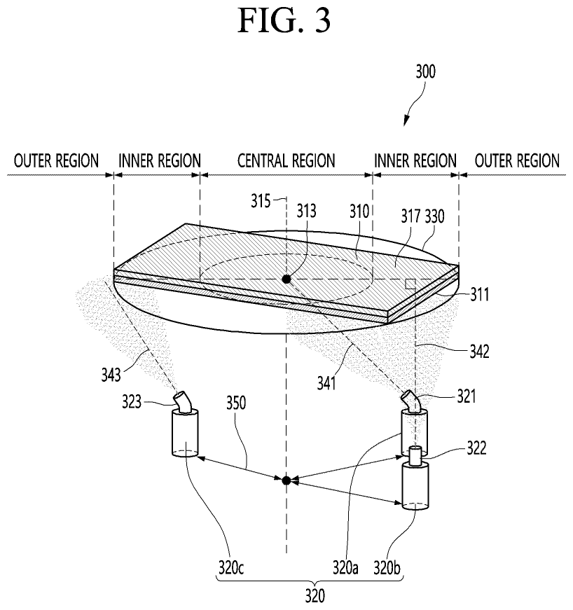

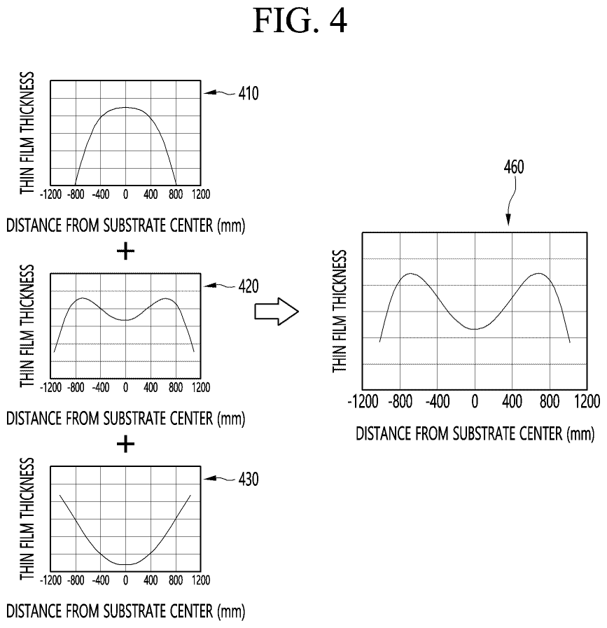

FIG. 3 is a diagram illustrating a deposition system according to an embodiment of the present invention. FIG. 4 is a graph showing a thin film thickness of a substrate on which deposition is performed by the deposition system according to the embodiment of the present invention.

First, referring to FIG. 3, a deposition system 300 includes a substrate 310 and a plurality of point evaporation sources 320 that spray a deposition material onto the substrate 310, and spraying directions of at least two of the plurality of point evaporation sources 320 are different from each other.

Referring to FIG. 3, the substrate 310 may be a rectangular panel. Each point evaporation source 320 may include a cylindrical crucible and a nozzle. A direction in which the point evaporation source 320 sprays the deposition material may be adjusted by the nozzle of the point evaporation source 320. At least two of the plurality of point evaporation sources 320 may spray different deposition materials.

Referring to FIG. 3, at least two of the plurality of point evaporation sources 320 may be disposed at substantially the same horizontal distance 350 from a central axis of the substrate 310. In this case, the central axis of the substrate 310 may be a normal of the substrate passing through a center 313 of the substrate. Further, “substantially the same” includes not only a value being completely the same, but also an error range generally generated by those skilled in the art being applied. Further, the horizontal distance 350 may be the shortest distance between the point evaporation source 320 and the central axis. Further, the shortest distances between the at least two point evaporation sources and the substrate 310 may be substantially the same.

Referring to FIG. 3, the substrate 310 may be fixed so that a front surface 311 of the substrate faces a ground, and may rotate with the central axis of the substrate 310 as a rotation axis 315. Accordingly, at least two of the plurality of point evaporation sources 320 may be disposed to have substantially the same shortest distance from the rotation axis 315 of the substrate. Further, the horizontal distance 350 may be the shortest distance between the point evaporation source 320 and the rotation axis 315.

Referring to FIG. 3, a circular deposition region 330 with a diagonal of the substrate 310 as a diameter may be formed as the substrate 310 rotates. The deposition region 330 may be a maximum region that vertices of the rectangular substrate 310 draw as the substrate 310 rotates. Accordingly, when the spraying direction of the point evaporation source 320 is adjusted so that the deposition material is uniformly applied to the deposition region 330, the deposition material may be uniformly applied to the substrate 310.

Referring to FIG. 3, the deposition region 330 may include a circular central region. A center of the central region may be the center 313 of the substrate, and a diameter of the central region may be smaller than that of the deposition region 330. The central region may be a circular region with a center of a circle that is the same as the center 313 of the substrate and a diameter at a predetermined proportion or less to the diameter of the deposition region 330 as a diameter of the circle. For example, the central region may be a circular region with a center of a circle that is the same as the center 313 of the substrate and a diameter of the circle of half or less than the diameter of the deposition region 330. Alternatively, the central region may be a circular region with a center of a circle that is the same as the center 313 of the substrate and a diameter of the circle that is 30% or less of the diameter of the deposition region 330.

Referring to FIG. 3, the deposition region 330 may include an inner region in the shape of a ring. An outer diameter of the inner region may be the same as the diameter of the deposition region 330, and an inner diameter of the inner region may be smaller than the diameter of the deposition region 330. Accordingly, the inner region may be a region in the deposition region 330 whose center is empty in a circular shape. Further, the inner region may be a region other than the central region in the deposition region 330.

Referring to FIG. 3, an outer region may be a region external to the deposition region 330. Since the point evaporation source 320 sprays the deposition material in a cone shape over a wide region, the deposition material may be applied to a part of the deposition region 330 even when the point evaporation source 320 sprays the deposition material toward the outer region.

Referring to FIG. 3, at least one of the plurality of point evaporation sources 320 may be a center spray point evaporation source that sprays the deposition material toward the central region. A first point evaporation source 320a is coupled to a first nozzle 321, which sprays a deposition material in a first spraying direction 341. In this case, since the first spraying direction 341 is directed toward the central region, the first point evaporation source 320a may be a center spray point evaporation source.

Referring to FIG. 3, the center spray point evaporation source may include a nozzle tilted a predetermined angle toward the central region to spray the deposition material toward the central region. In this case, the “predetermined angle” may be any angle set in advance, and the same applies to the following embodiments. The first point evaporation source 320a includes the first nozzle 321, and the first nozzle 321 is tilted about 45° to the left from a vertical upward direction toward the central region.

Referring to FIG. 3, at least one of the plurality of point evaporation sources 320 may be an inner-side spray point evaporation source that sprays the deposition material toward the inner region. The second point evaporation source 320b is coupled to a second nozzle 322, which sprays the deposition material in a second spraying direction 342. In this case, since the second spraying direction 342 is directed toward the inner region, the second point evaporation source 320b may be an inner-side spray point evaporation source.

Referring to FIG. 3, the inner-side spray point evaporation source may include a nozzle that sprays the deposition material vertically toward the inner region. The second point evaporation source 320b includes the second nozzle 322, and the second nozzle 322 sprays the deposition material vertically toward the inner region.

Referring to FIG. 3, at least one of the plurality of point evaporation sources 320 may be an outer-side spraying point evaporation source that sprays the deposition material toward the outer region. The third point evaporation source 320c is coupled to a third nozzle 323, which sprays the deposition material in a third spraying direction 343. In this case, since the third spraying direction 343 is directed toward the outer region, the third point evaporation source 320c may be an outer-side spray point evaporation source.

Referring to FIG. 3, the outer-side spray point evaporation source may include a nozzle tilted a predetermined angle toward the outer region to spray the deposition material toward the outer region. The third point evaporation source 320c includes the third nozzle 323, and the third nozzle 323 is tilted about 30° to the left from a vertical upward direction toward the outer region.

Referring to FIG. 3, the plurality of point evaporation sources 320 include one center spray point evaporation source, one inner-side spray point evaporation source, and one outer-side spray point evaporation source. However, the number or spraying direction of point evaporation sources 320 is not limited and may vary in various ways, and the same applies to embodiments below.

Referring to FIGS. 3 and 4, in the case of a thin film thickness 410 according to a distance of a substrate on which deposition is performed by the first point evaporation source 320a, which is a center spray point evaporation source, a thin film thickness at an edge of the substrate is the smallest, and a thin film thickness at the center 313 of the substrate is the largest. Thus, the center spray point evaporation source may be a point evaporation source 320 that deposits the deposition material most thickly at the center 313 of the substrate.

Referring to FIGS. 3 and 4, in the case of a thin film thickness 420 according to a distance of a substrate on which deposition is performed by the second point evaporation source 320b, which is an inner-side spray point evaporation source, thin film thicknesses at the center 313 of the substrate and an edge of the substrate are small, and a thin film thickness in the inner region of the substrate is large. Thus, the inner-side spray point evaporation source may be a point evaporation source 320 that deposits the deposition material most thickly in a certain region between the center 313 of the substrate and the edge of the substrate.

Referring to FIGS. 3 and 4, in the case of a thin film thickness 430 according to distance of a substrate on which deposition is performed by the third point evaporation source 320c, which is an external spray point evaporation source, a thin film thickness at the center 313 of the substrate is small and a thin film thickness at an edge of the substrate is the largest. Thus, the external spray point evaporation source may be a point evaporation source 320 that deposits the deposition material most thickly at the edge of the substrate.

Referring to FIGS. 3 and 4, the uniformity of a total thin film thickness 460 according to a distance of the substrate on which deposition is performed by the deposition system 300 is calculated as 4.6%. On the other hand, the uniformity of a total thin film thickness 260 according to a distance of a substrate on which deposition is performed by the conventional deposition system 100 is calculated as 11.1%. Therefore, according to the above-described embodiment, in the deposition system 300, since the spraying directions of the plurality of point evaporation sources 320 can be adjusted to be complementary to each other, deposition on the substrate 310 can be performed very uniformly.

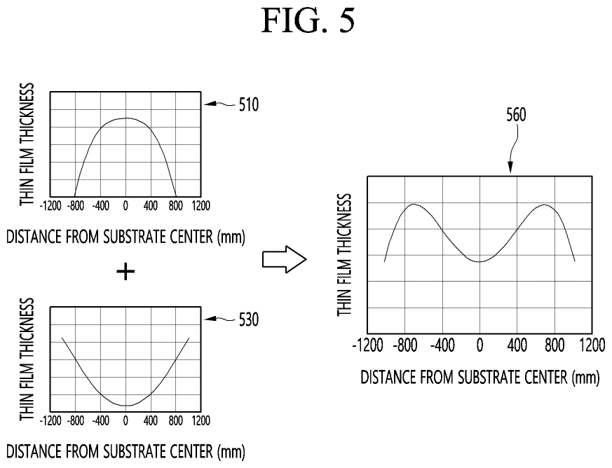

FIG. 5 is a graph showing a thin film thickness of a substrate on which deposition is performed by a deposition system according to another embodiment of the present invention. The deposition system in this embodiment includes one center spray point evaporation source and one outer-side spray point evaporation source.

Referring to FIG. 5, in the case of a thin film thickness 510 according to a distance of a substrate on which deposition is performed by the center spray point evaporation source, a thin film thickness at an edge of the substrate is the smallest, and a thin film thickness at a center of the substrate is the largest. In the case of a thin film thickness 530 according to a distance of a substrate on which deposition is performed by the outer-side spray point evaporation source, a thin film thickness at a center of the substrate is the smallest, and a thin film thickness at an edge is the largest.

Referring to FIG. 5, the uniformity of a total thin film thickness 560 according to a distance of the substrate is calculated as 5.9%. This value indicates improved uniformity compared to 11.1% that is the uniformity of the total thin film thickness 260 according to a distance of the substrate on which deposition is performed by the conventional deposition system 100.

Therefore, according to the above-described embodiment, with the deposition system including only two point evaporation sources having different spraying directions, it is possible to acquire a substrate on which deposition is performed with improved uniformity than the conventional deposition system 100. Thus, in the deposition system, since the number of point evaporation sources used to deposit the substrate can be reduced, it is possible to reduce management and repair costs of the point evaporation sources.

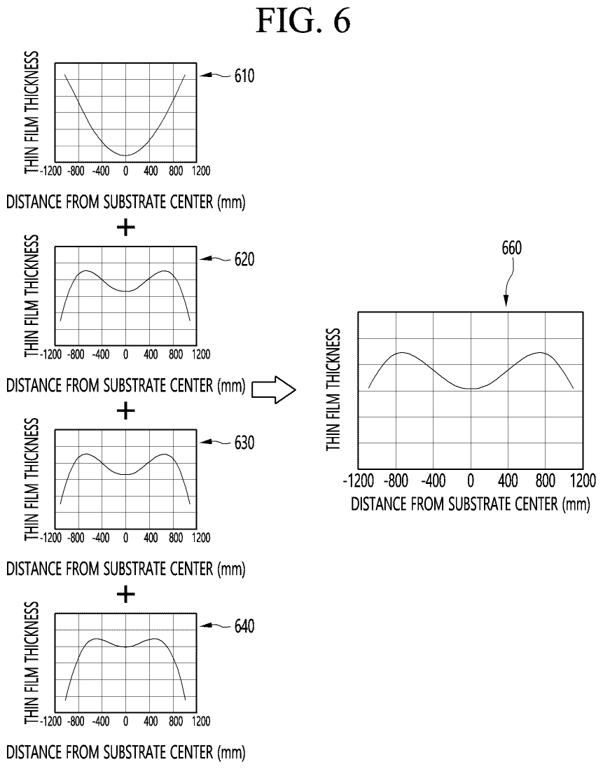

FIG. 6 is a graph showing a thin film thickness of a substrate on which deposition is performed by a deposition system according to still another embodiment of the present invention. The deposition system in this embodiment includes one outer-side spray point evaporation source and three inner-side spray point evaporation sources.

It can be confirmed from FIG. 6 that, since a thin film thickness 620 according to a distance of a substrate on which deposition is performed by a first inner-side spray point evaporation source is similar to a thin film thickness 630 according to a distance of a substrate on which deposition is performed by a second inner-side spray point evaporation source, spraying directions of the first inner-side spray point evaporation source and the second inner-side spray point evaporation source are similar to each other. On the other hand, it can be confirmed that a spraying direction of the third inner-side spray point evaporation source is closer to the center of the substrate than the spraying direction of the first inner-side spray point evaporation source or the spraying direction of the second inner-side spray point evaporation source.

It can be confirmed from FIG. 6 that the uniformity of a total thin film thickness 660 according to a distance of the substrate is 3.5%, and a substrate can be acquired with the uniformity higher than the total thin film thickness 460 according to a distance of the substrate on which deposition is performed by the deposition system 300 using the three point evaporation sources 320.

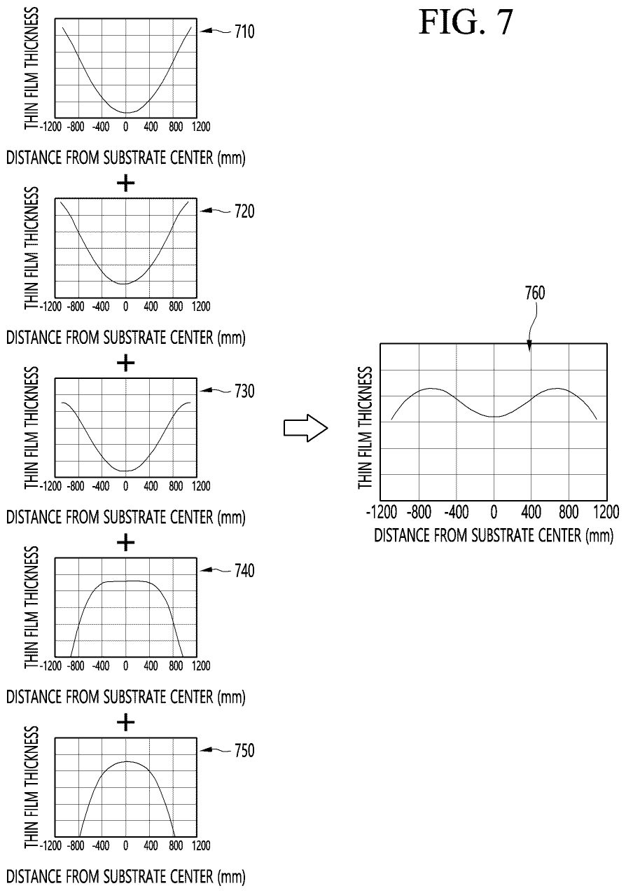

FIG. 7 is a graph showing a thin film thickness of a substrate on which deposition is performed by a deposition system having five evaporation sources according to still another embodiment of the present invention. The deposition system in this embodiment includes three outer-side spray point evaporation sources and two center spray point evaporation sources.

It can be confirmed from FIG. 7 that the uniformity of a total thin film thickness 760 according to a distance of a substrate is 2.7%, and a substrate can be acquired with the uniformity higher than the total thin film thickness 660 according to a distance of the substrate on which deposition is performed by the deposition system using four point evaporation sources.

According to the above-described embodiment, since the spraying direction of each point evaporation source in the deposition system can be adjusted, the deposition system may have a larger number of point evaporation sources to further improve the uniformity of the thin film.

Further, according to the above-described embodiment, the deposition system can improve the uniformity of the thickness of the thin film deposited on the substrate by adjusting the spraying direction of each of the plurality of point evaporation sources to the outside. In particular, the deposition system can uniformly deposit the substrate by tilting the spraying directions of the point evaporation sources to the outside even when the substrate has a large area.

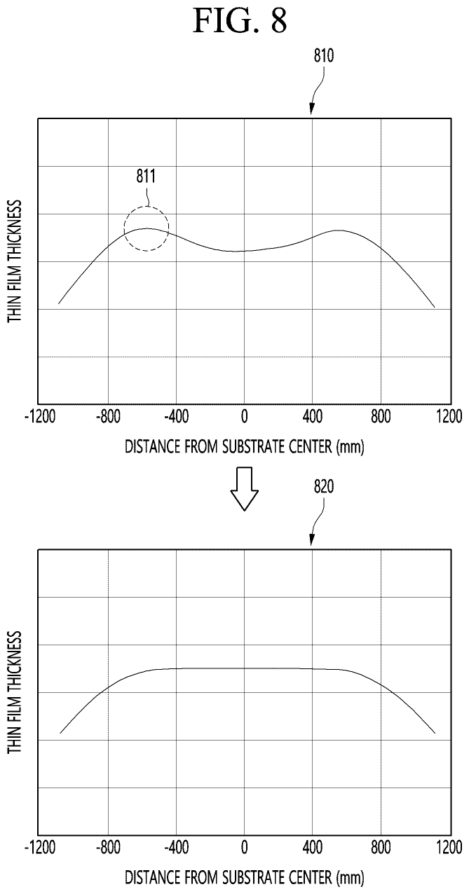

FIG. 8 is a graph showing a thin film thickness of a substrate on which deposition is performed by a point evaporation source whose nozzle is replaced with a nozzle having a different diameter according to still another embodiment of the present invention.

Nozzles of at least two of a plurality of point evaporation sources may have different diameter. When the diameters of the nozzles coupled to the respective point evaporation sources are different, angles and spraying forces at which the respective point evaporation sources spray a deposition material may also be different. Specifically, when evaporation amounts of the deposition material are the same, a smaller nozzle diameter results in the point evaporation source spraying the deposition material more weakly over a wide region, and a larger nozzle diameter results in the point evaporation source spraying the deposition material more strongly over a narrow region. Accordingly, with the nozzle, it is possible to adjust not only the spraying direction of the point evaporation source, but also the spraying angle and the spraying force thereof.

Referring to FIG. 8, a graph of a thin film thickness 810 according to a distance of a substrate on which deposition is performed with a nozzle having a large diameter shows that a thin film in a portion 811 in the spraying direction of the point evaporation source is relatively thick, whereas a graph of a thin film thickness 820 according to a distance of a substrate on which deposition is performed with a nozzle having a small diameter shows an overall gradual thin film thickness.

According to the above-described embodiment, the deposition system can improve the uniformity of the thin film on the substrate by changing the diameter of the nozzle coupled to each point evaporation source, and in particular, can prevent an edge-drop phenomenon or a center-drop phenomenon.

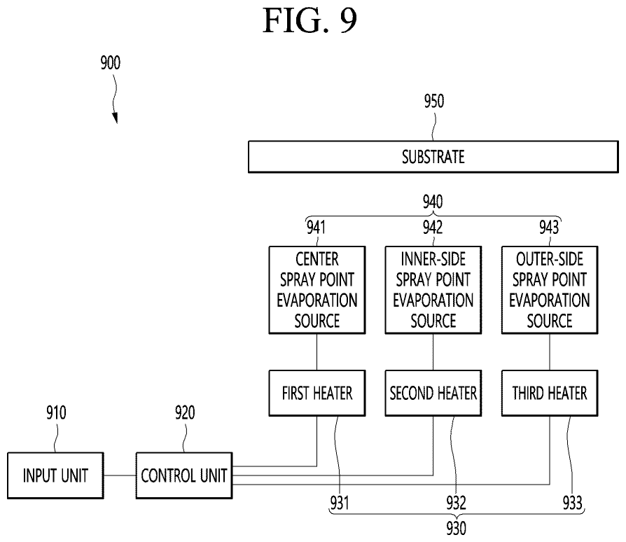

FIG. 9 is a block diagram illustrating a deposition system according to still another embodiment of the present invention.

Referring to FIG. 9, a deposition system 900 may further include a control unit connected to independently control a spraying amount of each of a plurality of point evaporation sources. The deposition system 900 may include a plurality of heaters 930 thermally coupled to respective point evaporation sources 940, a control unit 920 connected to control a heating degree of each heater 930, and an input unit 910 for transferring a user input to the control unit 920. Accordingly, the user inputs an evaporation amount of each point evaporation source 940 to the input unit 910, an input value is transferred to the control unit 920, and the control unit 920 controls the heating degree of each heater 930 so that each point evaporation source 940 can spray a deposition material toward the substrate 950 with the input evaporation amount.

Referring to FIG. 9, the control unit 920 may control a spraying amount of a center spray point evaporation source so that the spraying amount is larger than that of at least one of the plurality of point evaporation sources 940. Specifically, the control unit 920 may control a heating degree of the first heater 931 to control the spraying amount of a center spray point evaporation source 941 so that the spraying amount of the center spray point evaporation source 941 is larger than that of at least one of the plurality of point evaporation sources 940. In this case, since a larger amount of deposition material is sprayed onto a center of the substrate, it is possible to prevent the center drop phenomenon of the thin film thickness.

Further, the control unit 920 may control a spraying amount of an inner-side spray point evaporation source so that the spraying amount is smaller than that of at least one of the plurality of point evaporation sources 940. Specifically, the control unit 920 may control a heating degree of a second heater 932 to control the spraying amount of an inner-side spray point evaporation source 942 so that the spraying amount of the inner-side spray point evaporation source 942 is smaller than those of the other point evaporation sources 940. In this case, since an amount of deposition material sprayed to a region between the center and an edge of the substrate decreases, it is possible to prevent an edge-drop phenomenon and a center-drop phenomenon of the thin film thickness.

Further, the control unit 920 may control a spraying amount of an outer-side spray point evaporation source so that spraying amount is larger than that of at least one of the plurality of point evaporation sources 940. Specifically, the control unit 920 may control a heating degree of a third heater 933 to control the spraying amount of an outer-side spray point evaporation source 943 so that the spraying amount of the outer-side spray point evaporation source 943 is larger than that of at least one of the plurality of point evaporation sources 940. In this case, since a larger amount of deposition material is sprayed to the edge of the substrate, it is possible to prevent the edge-drop phenomenon of the thin film thickness.

According to the above-described embodiment, the deposition system can perform uniform deposition on the substrate even when a shape, area, rotation speed of the substrate, or a distance to the substrate varies, by adjusting the spraying amount of each of the plurality of point evaporation sources 940.

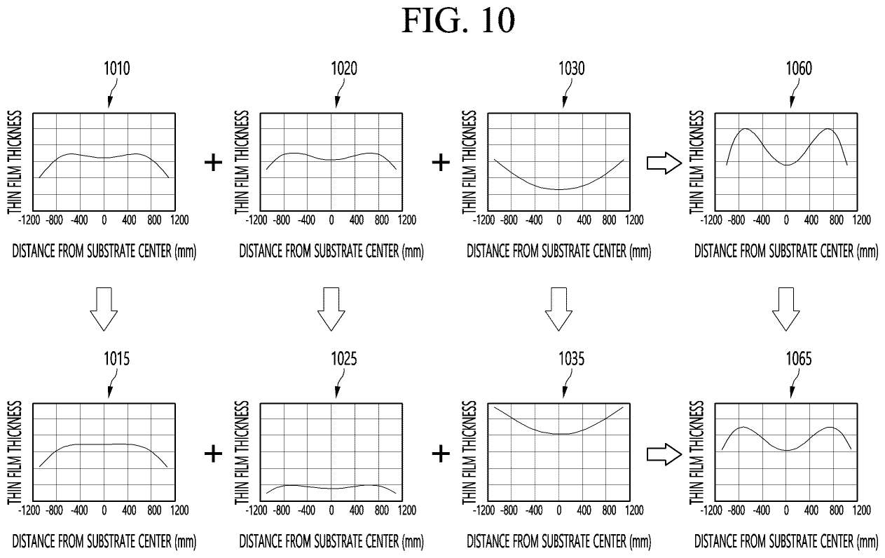

FIG. 10 is a graph showing a thin film thickness of a substrate on which deposition is performed by a deposition system in which each nozzle has an optimized diameter and spraying amount according to still another embodiment of the present invention.

Referring to FIG. 10, the plurality of point evaporation sources may have different spraying amounts, and respective nozzles combined to the plurality of point evaporation sources may have different diameters. The uniformity of a total thin film thickness 1060 according to a distance of the substrate before improvement is 4.6%.

In this state, when a diameter of a nozzle of a first point evaporation source is reduced, a thin film thickness 1015 according to a distance of the substrate on which deposition is performed by the first point evaporation source after improvement becomes more gradual than a thin film thickness 1010 before improvement.

Further, when an evaporation amount of a second point evaporation source is decreased, a thin film thickness 1025 according to a distance of a substrate on which deposition is performed by the second point evaporation source after improvement becomes overall smaller than a thin film thickness 1020 before improvement.

Further, when an evaporation amount of a third point evaporation source is increased and a diameter thereof is reduced, a thin film thickness 1035 according to a distance of a substrate on which deposition is performed by the third point evaporation source after improvement becomes overall larger and more gradual than a thin film thickness 1030 before improvement.

It can be confirmed that the uniformity of a total thin film thickness 1065 according to a distance of the substrate after improvement is 3.0%, and the thin film thickness is very uniform compared to that before improvement.

According to the above-described embodiment, it is possible to greatly improve the thin film uniformity of the substrate by changing the evaporation amounts of the respective point evaporation sources and the diameters of the nozzles in various ways so that the thin film thickness differences deposited by the respective point evaporation sources are complementary to each other.

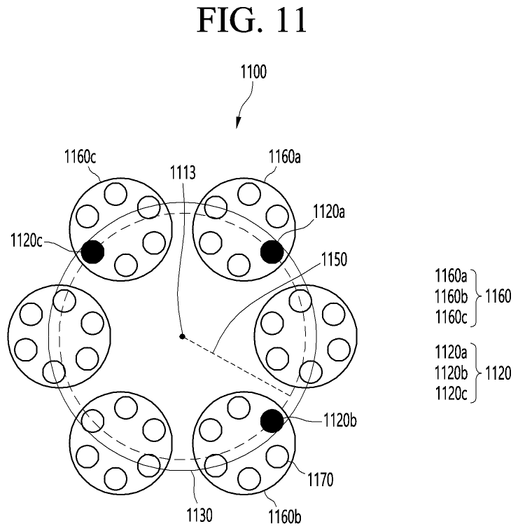

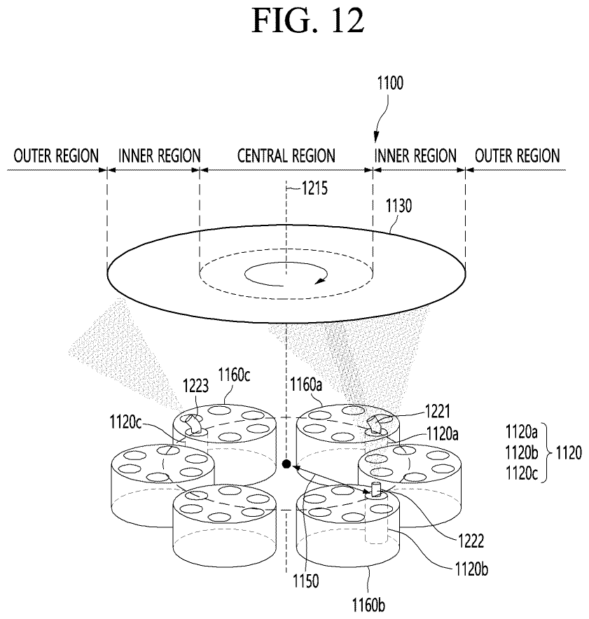

FIG. 11 is a diagram illustrating a revolver-type deposition system viewed from a normal direction of a substrate according to still another embodiment of the present invention. FIG. 12 is a diagram illustrating a deposition system according to still another embodiment of the present invention. FIG. 12 may be understood as a diagram three-dimensionally expressing a revolver-type deposition system 1100 in FIG. 11.

Referring to FIG. 11, the deposition system 1100 may further include a revolver 1160 including a first point evaporation source 1120a among a plurality of point evaporation sources 1120, and a first preliminary point evaporation source 1170 corresponding to the first point evaporation source 1120a. Further, the revolver 1160 may rotate to move the first preliminary point evaporation source 1170 to a position of the first point evaporation source 1120a.

Referring to FIG. 11, the deposition system 1100 may include a plurality of revolvers 1160. The first revolver 1160a includes the first point evaporation source 1120a and a plurality of preliminary point evaporation sources. The deposition system 1100 may further include five revolvers 1160 including a second revolver 1160b and a third revolver 1160c, in addition to the first revolver 1160a. Some of the revolvers 1160 may be inactive revolvers that do not include point evaporation sources 1120.

Referring to FIG. 11, the plurality of revolvers 1160 may rotate 60° counterclockwise after a preset time has elapsed. Accordingly, one of the preliminary point evaporation sources 1170 may be moved to a position of the point evaporation source 1120 that is spraying a deposition material. At the same time, the moved preliminary point evaporation source 1170 begins spraying the deposition material, while the point evaporation source 1120 may stop spraying the deposition material and be changed to a preliminary point evaporation source.

Referring to FIGS. 11 and 12, at least two of the point evaporation sources 1120 may be disposed at the same horizontal distance 1150 from a rotation axis 1215 of the substrate. Further, the horizontal distance 1150 of each point evaporation source 1120 may be smaller than a radius of a deposition region 1130.

Referring to FIGS. 11 and 12, in a deposition system 1200, the substrate rotates around the rotation axis 1215 so that the deposition region 1130 is formed. A first nozzle 1221 coupled to the first point evaporation source 1120a is a center spray point evaporation source that sprays a deposition material toward the central region, a second nozzle 1222 coupled to the second point evaporation source 1120b is an inner-side spray point evaporation source that sprays a deposition material toward the inner region, and a third nozzle 1223 coupled to the third point evaporation source 1120c is an outer-side spray point evaporation source that sprays a deposition material toward the outer region.

According to the above-described embodiment, with the deposition system 1100, it is possible to improve the uniformity of the thin film thickness of the substrate by adjusting the directions in which the respective point evaporation sources 1120 spray the deposition material even when the horizontal distances 1150 of the plurality of point evaporation sources 1120 are the same, by using the revolver scheme.

Further, the other embodiments described above are applied together so that the deposition system 1100 can adjust each nozzle and a heating amount of the heater to additionally adjust the spraying angle, spraying force, and spraying amount of each point evaporation source 1120. This makes it possible for the deposition system 1100 to deposit the substrate very uniformly.

The steps of the method or algorithm described in connection with the embodiments disclosed herein may be directly implemented by hardware, a software module, or a combination thereof executed by the control unit. The software module may reside in a RAM, flash memory, ROM, EPROM, EEPROM, register, hard disk, removable disk, CD-ROM, or any other form of recording or storage medium known in the art. An exemplary recording medium or storage medium is coupled to the control unit, and the control unit can read information from the recording medium or storage medium and write information to the recording medium or storage medium. Alternatively, the recording medium or storage medium may be integral with the control unit. The control unit and the recording medium or storage medium may reside within an application-specific integrated circuit (ASIC). The ASIC may reside within a user terminal. Alternatively, the control unit and the storage medium may reside as separate components within the user terminal.

Although the embodiments of the present invention have been described in greater detail with reference to the accompanying drawings, the present invention is not necessarily limited to these embodiments, and various variations may be made without departing from the technical spirit of the present invention. Accordingly, the embodiments disclosed herein are not intended to limit the technical spirit of the present invention, but rather to describe the technical spirit of the present invention, and the technical spirit of the present invention is not limited by these embodiments. Therefore, it should be understood that the embodiments described above are exemplary in all respects and not restrictive. The scope of protection of the present invention should be construed by the claims below, and all technical spirits within the scope equivalent thereto should be construed as being included in the scope of the rights of the present invention.

1. A deposition system comprising:
a substrate; and
a plurality of point evaporation sources configured to spray a deposition material onto the substrate, wherein
at least two of the plurality of point evaporation sources have different spraying directions.

2. The deposition system of claim 1, wherein the at least two of the plurality of point evaporation sources are disposed at substantially the same horizontal distance from a central axis of the substrate.

3. The deposition system of claim 1, wherein
the substrate rotates around a central axis of the substrate, and
a circular deposition region with a diagonal of the substrate as its diameter is formed as the substrate rotates.

4. The deposition system of claim 3, wherein
the deposition region includes a circular central region,
a center of the central region is the same as the center of the substrate,
the central region has a diameter smaller than the deposition region, and
at least one of the plurality of point evaporation sources is a center spray point evaporation source configured to spray the deposition material toward the central region.

5. The deposition system of claim 4, wherein the center spray point evaporation source includes a nozzle tilted a predetermined angle toward the central region to spray the deposition material toward the central region.

6. The deposition system of claim 4, wherein a spraying amount of the center spray point evaporation source is larger than that of at least one of the plurality of point evaporation sources.

7. The deposition system of claim 3, wherein
the deposition region includes an inner region in the shape of a ring,
the inner region has the same outer diameter as a diameter of the deposition region, and
at least one of the plurality of point evaporation sources is an inner-side spray point evaporation source configured to spray the deposition material toward the inner region.

8. The deposition system of claim 7, wherein the inner-side spray point evaporation source includes a nozzle configured to spray the deposition material vertically toward the inner region.

9. The deposition system of claim 7, wherein a spraying amount of the inner-side spray point evaporation source is smaller than that of at least one of the plurality of point evaporation sources.

10. The deposition system of claim 3, wherein at least one of the plurality of point evaporation sources is an outer-side spray point evaporation source configured to spray the deposition material toward an outer region that is a region external to the deposition region.

11. The deposition system of claim 10, wherein the outer-side spray point evaporation source includes a nozzle tilted a predetermined angle toward the outer region to spray the deposition material toward the outer region.

12. The deposition system of claim 10, wherein a spraying amount of the outer-side spray point evaporation source is larger than that of at least one of the plurality of point evaporation sources.

13. The deposition system of claim 1, wherein the nozzles of the at least two of the plurality of point evaporation sources have different diameters.

14. The deposition system of claim 1, further comprising:
a revolver including a first point evaporation source among the plurality of point evaporation sources and a first preliminary point evaporation source corresponding to the first point evaporation source, wherein
the revolver rotates to move the first preliminary point evaporation source to a position of the first point evaporation source.

15. The deposition system of claim 1, wherein the at least two of the plurality of point evaporation sources spray different deposition materials.
